(19) United States
(12) Patent Application Publication
(10) Pub. No.: US 2012/0108034 A1
(43) Pub. Date: May 3, 2012

(54) Substrate Structure Having Buried Wiring And Method For Manufacturing The Same, And Semiconductor Device And Method For Manufacturing The Same Using The Substrate Structure

(75) Inventors: Dae-Lok Bae, Seoul (KR); Gil-Heyun Choi, Seoul (KR); Byung-Lyul Park, Seoul (KR); Pil-Kyu Kang, Anyang-si (KR)

(73) Assignee: SAMSUNG ELECTRONICS CO., LTD., Suwon-si (KR)

(21) Appl. No.: 13/239,992

(22) Filed: Sep. 22, 2011

(30) Foreign Application Priority Data
Oct. 28, 2010 (KR) 10-2010-0106295

(51) Int. Cl. H01L 21/82

(52) U.S. Cl. 438/458; 257/E21.602

(57) ABSTRACT

Provided are a substrate structure which may solve problems generated in a manufacturing process while having a relatively low resistance buried wiring, a method for manufacturing the substrate structure, and a semiconductor device and a method for manufacturing the same using the substrate structure. The substrate structure may include a supporting substrate, an insulating layer disposed on the supporting substrate, a line-shaped conductive layer pattern disposed in the insulating layer to extend in a first direction, and a line-shaped semiconductor pattern disposed in the insulating layer and on the conductive layer pattern to extend in the first direction and having a top surface exposed to the outside of the insulating layer.

### CROSS-REFERENCE TO RELATED APPLICATION

This application claims priority under 35 U.S.C. 119 to Korean Patent Application No. 10-2010-0106295 filed on Oct. 28, 2010 in the Korean Intellectual Property Office (KIPO), the entire contents of which are herein incorporated by reference.

### BACKGROUND

1. Field

Example embodiments relate to a substrate structure having a buried wiring and a method for manufacturing the same, a semiconductor device and a method for manufacturing the same using the substrate structure. More particularly, example embodiments relate to a substrate structure which can solve problems generated in the manufacturing process while having low resistance buried wiring, a method for manufacturing the substrate structure, and a semiconductor device and a method for manufacturing the same using the substrate structure.

2. Description of the Related Art

Recently, as the integration level of semiconductor device drastically increases, a channel length of a transistor is reduced, resulting in a short channel effect, including an increased leakage current of the transistor, a reduced breakdown voltage, a continuously increasing current due to a drain voltage, and so on. Accordingly, it is necessary to develop a transistor which can effectively prevent the short channel effect. According to the increasing integration level of a semiconductor device, it is also necessary to develop a transistor having a design rule of an exposure limit or less.

However, such requirements cannot be satisfied with a conventional horizontal channel transistor in which a source region and a drain region are disposed on the same plane and a channel is formed between the source region and the drain region. To address this problem, a vertical channel transistor has been proposed, in which a source region and a drain region are vertically disposed up and down and a channel is formed between the source region and the drain region.

In the vertical channel transistor, however, an impurity region disposed under a gate electrode generally serves as a bit line, high electrical resistance may be imparted to the bit line. Thus, the bit line having high electrical resistance cannot easily transfer an externally applied voltage, thereby ultimately lowering electrical characteristics of the semiconductor device.

### SUMMARY

Example embodiments provide a substrate structure having low resistance buried wiring, which can solve problems generated in the manufacturing process to improve characteristics of a semiconductor device, and a method for manufacturing the substrate structure.

Example embodiments also provides a semiconductor device and a method for manufacturing the same using the substrate structure.

These and other objects of example embodiments will be described in or be apparent from the following description of the preferred embodiments.

In accordance with example embodiments, a substrate structure may include a supporting substrate, an insulating layer on the supporting substrate, a line-shaped conductive layer pattern in the insulating layer, the line-shaped conductive layer pattern extending in a first direction, and a line-shaped semiconductor pattern on the line-shaped conductive layer pattern, the line-shaped semiconductor pattern extending in the first direction and having a top surface exposed outside of the insulating layer.

In accordance with example embodiments, a method of manufacturing a substrate structure comprising may include forming a conductive layer on one surface of a semiconductor substrate, forming a line-shaped conductive layer pattern extending in a first direction by patterning the conductive layer, forming a line-shaped semiconductor pattern under the conductive layer pattern and extending in the first direction by etching the semiconductor substrate exposed by the conductive layer pattern to a depth, forming an insulating layer on the conductive layer pattern and the semiconductor pattern, disposing the insulating layer on a supporting substrate such that the one surface of the semiconductor substrate faces the supporting substrate, and removing a portion of the semiconductor substrate such that the insulating layer is exposed from a second surface of the semiconductor substrate.

In accordance with example embodiments, a method of manufacturing a substrate structure may include forming a stacked structure on a surface of a semiconductor substrate, the stacked structure comprising a line-shaped conductive pattern, etching the semiconductor substrate to form a line-shaped semiconductor pattern below the line-shaped conductive pattern, forming an insulating layer on the stacked structure, the line-shaped semiconductor pattern, and the semiconductor substrate, bonding the insulating layer to a support substrate, and cutting the semiconductor substrate to expose the insulating layer, wherein the stacked structure is used as an etch mask for forming the line-shaped semiconductor pattern.

In accordance with example embodiments, a substrate structure may include a supporting substrate, an insulating layer disposed on the supporting substrate, a line-shaped conductive layer pattern disposed in the insulating layer to extend in a first direction, and a line-shaped semiconductor pattern disposed in the insulating layer and on the conductive layer pattern to extend in the first direction and having a top surface exposed to the outside of the insulating layer.

In accordance with example embodiments a method of manufacturing a substrate structure may include forming a conductive layer on one surface of a semiconductor substrate, forming a line-shaped conductive layer pattern extending in a first direction by patterning the conductive layer, forming a line-shaped semiconductor pattern disposed under the conductive layer pattern and extending in the first direction by etching the semiconductor substrate exposed by the conductive layer pattern to a predetermined depth, forming an insulating layer on the conductive layer pattern and the semiconductor pattern, disposing the insulating layer on the supporting substrate such that the one surface of the semiconductor substrate faces the supporting substrate, and removing a portion of the semiconductor substrate such that the insulating layer is exposed from the other surface of the semiconductor substrate.

In accordance with example embodiments a semiconductor device may include a supporting substrate, an insulating layer disposed on the supporting substrate, a line-shaped conductive layer pattern disposed in the insulating layer to extend in a first direction, a line-shaped lower semiconductor pattern disposed on the conductive layer pattern to extend in the first direction, a pillar-shaped upper semiconductor pattern disposed on the lower semiconductor pattern, a gate line extending in a second direction intersecting with the first direction while contacting at least one sidewall of the upper semiconductor pattern, and a gate insulating layer interposed between the upper semiconductor pattern and the gate line, wherein the conductive layer pattern is surrounded by a capping layer pattern disposed on its bottom surface and a spacer disposed at its sidewalls.

In accordance with example embodiments a method of manufacturing a semiconductor device may include providing a substrate structure comprising a supporting substrate, an insulating layer disposed on the supporting substrate, a line-shaped conductive layer pattern disposed in the insulating layer to extend in a first direction, and a line-shaped semiconductor pattern disposed in the insulating layer and on the conductive layer pattern to extend in the first direction and having a top surface exposed to the outside of the insulating layer, forming a line-shaped lower semiconductor pattern disposed on the conductive layer pattern to extend in the first direction, and a pillar-shaped upper semiconductor pattern disposed on the lower semiconductor pattern, by patterning the semiconductor pattern, and forming a gate line extending in a second direction intersecting with the first direction while contacting at least one sidewall of the upper semiconductor pattern with a gate insulating layer interposed between the upper semiconductor pattern and the gate line.

### BRIEF DESCRIPTION OF THE DRAWINGS

The above and other features and advantages of example embodiments will become more apparent by describing in detail example embodiments with reference to the attached drawings in which:

FIG. 1 is a perspective view of a substrate structure according to example embodiments;

FIG. 2 is a cross-sectional view of the substrate structure shown in FIG. 1, taken along the line A-A′;

FIGS. 3 to 11 illustrate processes in a method of manufacturing the substrate structure shown in FIGS. 1 and 2;

FIG. 12 is a perspective view of a semiconductor device according to example embodiments;

FIG. 13 is a cross-sectional view of the semiconductor device shown in FIG. 12, taken along lines A-A′, B-B′ and C-C′;

FIGS. 14 to 18 illustrate processes in a method of manufacturing the substrate structure shown in FIGS. 12 and 13;

FIG. 19 is a perspective view of a semiconductor device according to example embodiments; and

FIG. 20 is a plan view of the semiconductor device shown in FIG. 19.

### DETAILED DESCRIPTION

The present invention will now be described more fully hereinafter with reference to the accompanying drawings, in which example embodiments are shown. This invention may, however, be embodied in different forms and should not be construed as limited to example embodiments as set forth herein. Rather, example embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Example embodiments will be described with reference to perspective views, cross-sectional views, and/or plan views, in which example embodiments are shown. Thus, the profile of an exemplary view may be modified according to manufacturing techniques and/or allowances. That is, example embodiments are not intended to limit the scope of the present invention but cover all changes and modifications that can be caused due to a change in manufacturing process. Thus, regions shown in the drawings are illustrated in schematic form and the shapes of the regions are presented simply by way of illustration and not as a limitation.

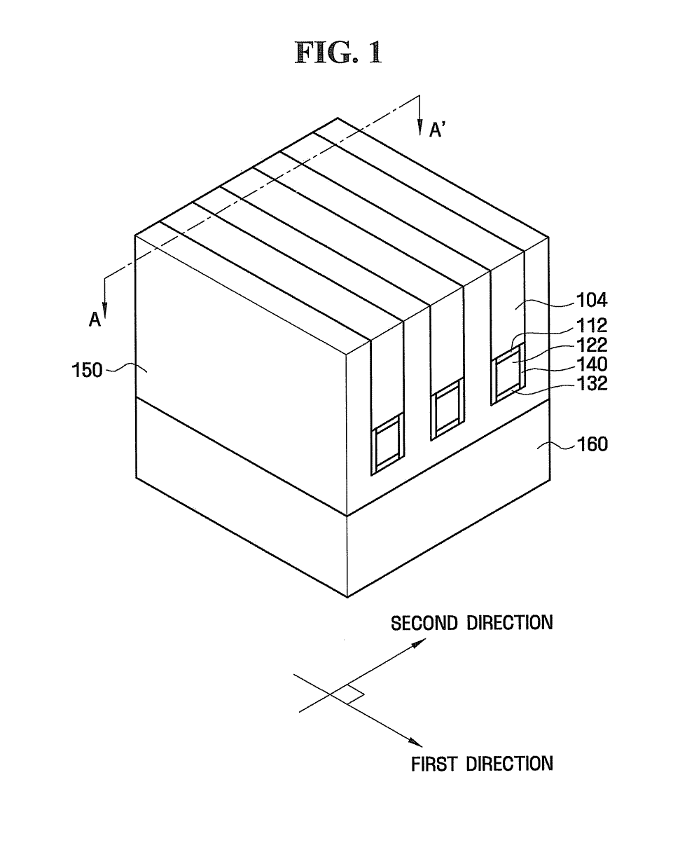

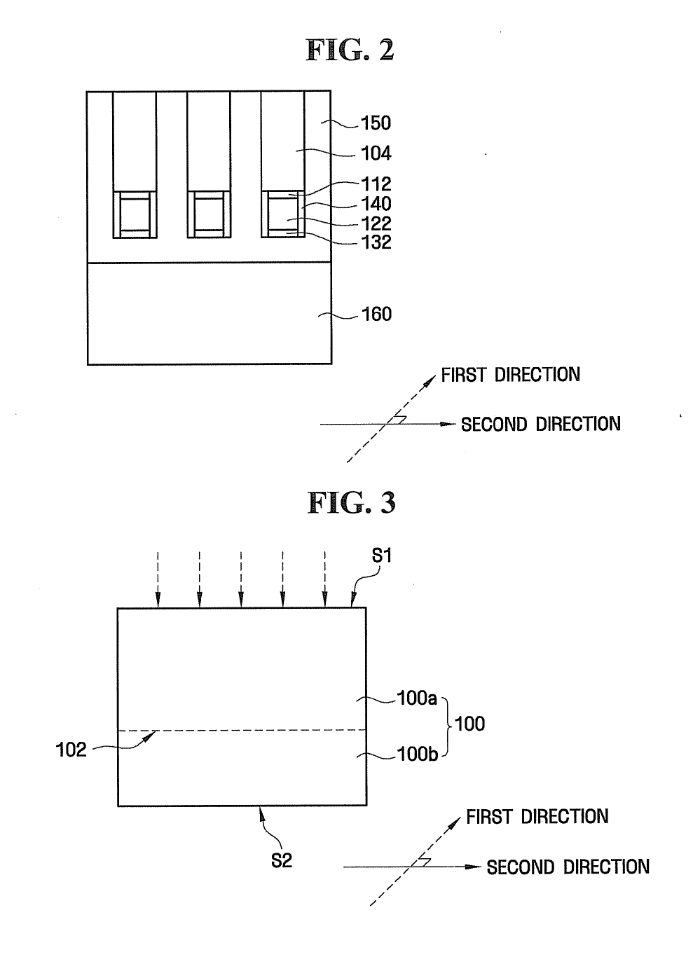

Hereinafter, a substrate structure according to example embodiments and a manufacturing method thereof will be described with reference to FIGS. 1 to 11. FIG. 1 is a perspective view of a substrate structure according to example embodiments, FIG. 2 is a cross-sectional view of the substrate structure shown in FIG. 1, taken along the line A-A′ and FIGS. 3 to 11 illustrate processes in a method of manufacturing the substrate structure shown in FIGS. 1 and 2.

First, the substrate structure according to example embodiments will be described.

In example embodiments, the substrate structure may include a supporting substrate 160, an insulating layer 150 disposed on the supporting substrate 160, a line-shaped conductive layer pattern 122 disposed in the insulating layer 150, and a line-shaped semiconductor pattern 104 disposed on the conductive layer pattern 122. In example embodiments, the line-shaped semiconductor pattern 104 and the conductive layer pattern 122 may extend in the first direction as shown in FIGS. 1 and 2. In example embodiments, the line-shaped conductive layer pattern 122 may be buried in the insulating layer 150. Thus, the line-shaped conductive layer pattern 122 may serve as a buried wiring. Accordingly, in example embodiments, the substrate structure may be a substrate structure having a buried wiring. Various components of the substrate structure according to example embodiments will now be described in more detail.

In example embodiments, the supporting substrate 160 may support structures thereon. The supporting substrate 160, however, may not be a substrate on which unit elements, for example, transistors, are substantially formed. Thus, a variety of semiconductor substrates may be used as the supporting substrate 160. For example, the supporting substrate 160 may be any one selected among a single crystalline silicon substrate, an amorphous silicon substrate, a polysilicon substrate. In addition, the supporting substrate 160 may include even a substrate that includes crystal defects or particles. In addition, even a low-level substrate determined as an inappropriate substrate in forming an element may be used as the supporting substrate 160.

The insulating layer 150 having required components (for example, the conductive layer pattern 122, or the semiconductor pattern 104) may be disposed on the supporting substrate 160. One surface of the insulating layer 150 may be directly bonded to a top surface of the supporting substrate 160 and may be disposed on the supporting substrate 160. To this end, the surface of the insulating layer 150 bonded to the top surface of the supporting substrate 160 may be planarized. The insulating layer 150 may include a silicon oxide layer. The silicon oxide layer may include a high density plasma (HDP) oxide layer, a spin on glass (SOG) oxide layer, a tetraethyl orthosilicate (TEOS) layer, an oxide layer formed by radical oxidation, and so on.

In example embodiments, the plurality of line-shaped conductive layer patterns 122 may extend in the first direction and may be disposed to be spaced apart from each other in the insulating layer 150 to a depth from a top surface of the insulating layer 150. In example embodiments, the depth may or may not be predetermined. In addition, the plurality of semiconductor patterns 104 may likewise extend in the first direction and may also be disposed to be spaced apart from each other in the insulating layer 150 and on the conductive layer patterns 122. In example embodiments, top surfaces of the semiconductor patterns 104 and the top surface of the insulating layer 150 may be disposed at substantially the same height. That is to say, the top surfaces of the semiconductor patterns 104 may be exposed to the outside of the insulating layer 150. As shown, the line-shaped semiconductor patterns 104 and the line-shaped conductive layer patterns 122 overlap each other on a plane and have substantially the same shape. In example embodiments, a second direction width of each of the semiconductor patterns 104 may be an extent greater than that of each of the conductive layer patterns 122. In example embodiments, the extent may or may not be predetermined. In example embodiments, the extent may be substantially the same as a second direction width of a spacer 140 disposed at either side of the conductive layer patterns 122.

The conductive layer patterns 122 may include a metal or a metal silicide material. Examples of the conductive layer patterns 122 may include tungsten, aluminum, copper cobalt, nickel silicide, cobalt silicide, and tungsten silicide. The conductive layer patterns 122 may be formed using these materials alone or in combination of two or more of these materials. In addition, the semiconductor patterns 104 may include a single crystalline semiconductor, for example, single crystalline silicon. However, materials forming the conductive layer patterns 122 and the semiconductor patterns 104 are not limited to those illustrated herein, but various materials other than those illustrated herein may be used for the conductive layer patterns 122 or the semiconductor patterns 104.

A barrier layer pattern 112 may further be disposed on the top surface of each of the conductive layer patterns 122. The barrier layer pattern 112, disposed between the semiconductor patterns 104 and the conductive layer patterns 122, may be a kind of a diffusion barrier layer functioning to prevent or reduce metal elements or conductive elements included in the conductive layer patterns 122 from being diffused into the semiconductor patterns 104 or to prevent or reduce semiconductor elements in the semiconductor patterns 104 from being diffused into the conductive layer patterns 122. The barrier layer pattern 112 may serve as a diffusion barrier layer and may provide for an ohmic contact between the semiconductor patterns 104 and the conductive layer patterns 122 while improving a contact characteristic. The barrier layer pattern 112 may include a metal, metal nitride or a metal silicide material. For example, the barrier layer pattern 112 may be made of titanium, titanium nitride, tantalum, tantalum nitride, tungsten nitride, tungsten silicide, cobalt silicide, nickel silicide, or the like. The barrier layer pattern 112 may be formed using these materials alone or in combination of two or more of these materials.

Additionally, capping layer patterns 132 may further be disposed on a bottom surface of the conductive layer patterns 122. The capping layer patterns 132 used for performing a patterning process in a manufacturing method of a substrate structure to be described later may remain on the bottom surface of the conductive layer patterns 122, as shown, which will later be described in more detail. The capping layer patterns 132 may include an insulating material, for example, silicon oxide, silicon nitride, or silicon oxynitride.

The spacer 140 may further be disposed on both sidewalls of a stack structure in which the capping layer patterns 132, the conductive layer patterns 122 and the barrier layer pattern 112 are sequentially stacked. The spacer 140 used for performing the patterning process in the manufacturing method of the substrate structure to be described later, may remain on the both sidewalls of the capping layer patterns 132, the conductive layer patterns 122 and the barrier layer pattern 112, as shown, which will later be described in more detail. The spacer 140 may include an insulating material such as silicon oxide, silicon nitride, or silicon oxynitride.

In example embodiments, a semiconductor device, for example, a transistor, may use the substrate structure. In this case, the semiconductor patterns 104 may be provided as an active region and the insulating layer 150 may be provided as an isolation region that separates the semiconductor patterns 104 from each other. In addition, the conductive layer patterns 122 disposed under the semiconductor patterns 104 may be separated from each other by the insulating layer 150 and may be provided as a buried wiring. For example, the conductive layer patterns 122 may be used as bit lines for applying a voltage to a drain region of a transistor.

Next, a method of manufacturing the substrate structure shown in FIGS. 1 and 2 will be described.

First, referring to FIG. 3, a semiconductor substrate 100 to be bonded to the supporting substrate 160 is provided. Here, a portion of the semiconductor substrate 100 is provided as a semiconductor layer for forming a device, for example, a transistor, that is, as an active region. To this end, the semiconductor substrate 100 may be made of a single crystalline semiconductor, for example, single crystalline silicon, but example embodiments are not limited thereto. Rather, the semiconductor substrate 100 may be made of various semiconductor materials. In the following description, for convenience of explanation, of two surfaces of the semiconductor substrate 100, a surface disposed at a side to be bonded to the supporting substrate 160, is referred to as a first surface S1, and a surface disposed opposite to the first surface S1 is referred to as a second surface S2.

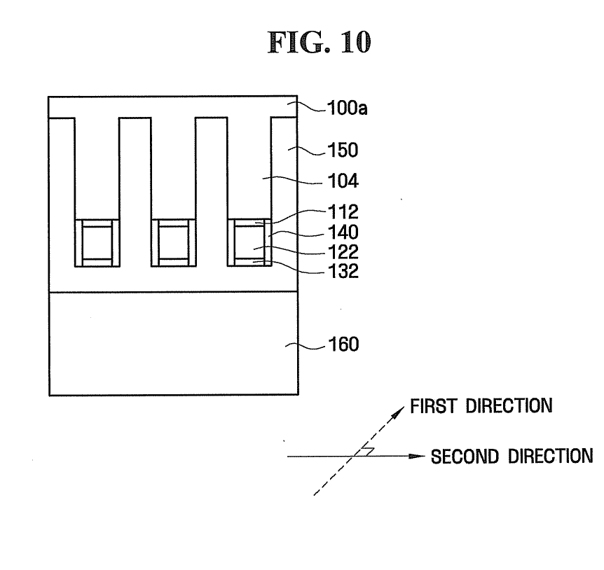

Subsequently, an ion implantation layer 102 is formed in the semiconductor substrate 100. The ion implantation layer 102 is a surface cut in a subsequent process (see FIG. 10) and may be formed using, for example, a hydrogen ion implantation process, on the first surface S1. The semiconductor substrate 100 may be divided into an upper part 100a and a lower part 100b by the ion implantation layer 102. Here, the upper part 100a of the semiconductor substrate 100 is provided as a semiconductor layer and the lower part 100b is removed in a subsequent cutting process (see FIG. 10). If necessary, the ion implantation layer 102 may be formed to a depth from the first surface S1. In example embodiments the depth may or may not be predetermined.

In the ion implantation process, atom or molecule ions are accelerated to have energy high enough to penetrate into a target material surface layer under a high voltage, and the accelerated ions are allowed to collide with a target material to be injected into the target material. Therefore, the magnitude of the ion implantation energy for accelerating ions may be adjusted, thereby adjusting a depth of the ion implantation layer 102. In addition, the amount of injected ions may be adjusted, thereby adjusting an ionic distribution of the ion implantation layer 102.

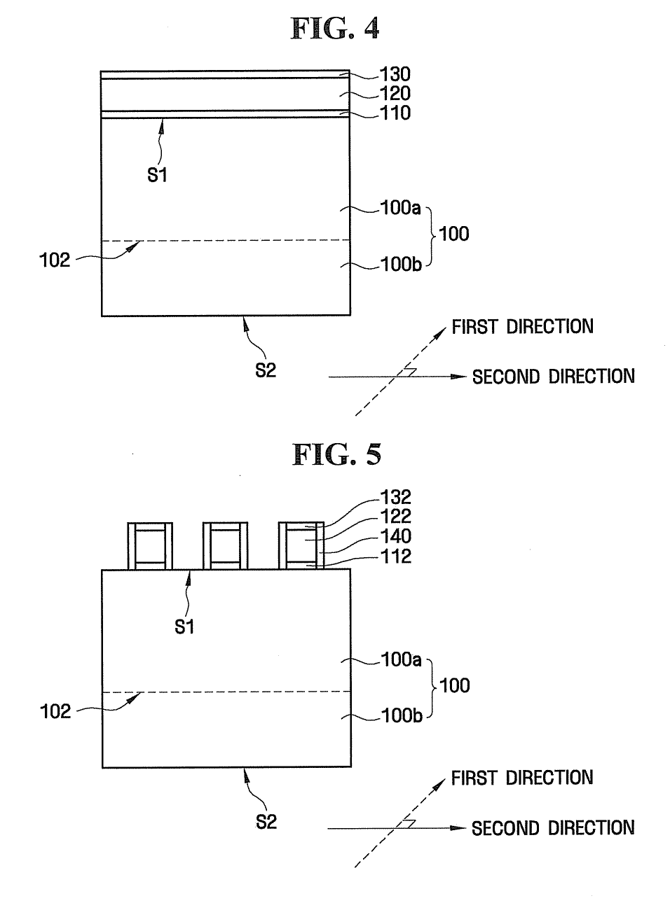

In example embodiments, since the ion implantation layer 102 is likely to be cut at a reference temperature, e.g., 500° C. or higher (the reference temperature may or may not be predetermined), processes performed between the process of forming the ion implantation layer 102 (see FIGS. 4 to 9) and the subsequent cutting process (see FIG. 10) may be performed above the reference temperature, e.g., 500° C. or lower. This will later be described in more detail again.

Referring to FIG. 4, a barrier layer 110 may be formed on the first surface S1 of the semiconductor substrate 100. The barrier layer 110 may be formed to prevent or reduce metal elements or conductive elements included in the conductive layer 120 from being diffused into the semiconductor substrate 100 or to prevent or reduce semiconductor elements in the semiconductor substrate 100 from being diffused into the conductive layer 120.

The barrier layer 110 may be formed using various deposition methods, for example, sputtering or chemical vapor deposition (CVD). In example embodiments, the barrier layer 110 may be deposited at a temperature of 500° C. or lower. In addition, the barrier layer 110 may be foamed by depositing a metal, metal nitride or a metal silicide material. For example, the barrier layer 110 may be made of titanium, titanium nitride, tantalum, tantalum nitride, tungsten nitride, tungsten silicide, cobalt silicide, or nickel silicide. The barrier layer 110 may be formed using these materials alone or in combination of two or more of these materials.

Next, a conductive layer 120 for forming a buried wiring may be formed on the barrier layer 110. The conductive layer 120 may be formed using various deposition methods. In example embodiments, the conductive layer 120 may be deposited at a temperature of 500° C. or lower. In addition, the conductive layer 120 may be formed by depositing a metal, or a metal silicide material. For example, the conductive layer 120 may be made of tungsten, aluminum, copper cobalt, nickel silicide, cobalt silicide, or tungsten silicide. The conductive layer 120 may be formed using these materials alone or in combination of two or more of these materials.

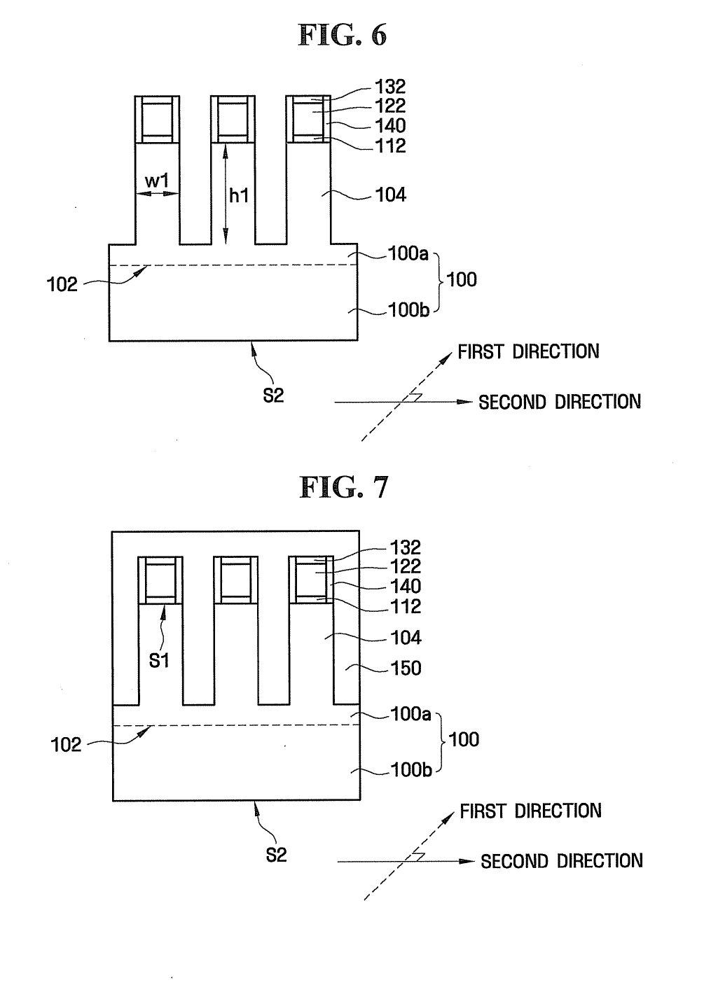

In example embodiments, a capping layer 130 may be formed on the conductive layer 120. The capping layer 130 may serve as an etch mask while protecting the conductive layer 120 in processes of etching the conductive layer 120 (see FIG. 5) and etching the semiconductor substrate 100 (see FIG. 6), which will later be described. The capping layer 130 may be formed using various deposition methods. In example embodiments, the capping layer 130 may be deposited at a temperature of 500° C. or lower. In addition, the capping layer 130 may be formed by depositing an insulating material, for example, silicon oxide, silicon nitride, or silicon oxynitride, on the conductive layer 120.

In example embodiments, the forming of the barrier layer 110 may be omitted from the processes shown in FIG. 4 according to the configuration of the conductive layer 120.

Referring to FIG. 5, a mask pattern (not shown) covering a potential region where a buried wiring is to be formed may be formed on the capping layer 130, and the capping layer 130 may be anisotropically etched using the mask pattern as an etch mask to form capping layer patterns 132. In example embodiments, the mask pattern (not shown) may or may not be predetermined. The conductive layer 120 and the barrier layer 110 may be anisotropically etched using the mask pattern and/or the capping layer patterns 132 as etch masks to form the conductive layer patterns 122 and the barrier layer pattern 112.

In example embodiments, the buried wiring (122 of FIGS. 1 and 2) may extend in the first direction, and a plurality of buried wirings may be formed to be spaced apart from each other. Thus, the mask pattern may be shaped of a line extending in the first direction so as to cover the line-shaped buried wiring. Therefore, as the result of this process, a stack structure may be formed, including the line-shaped barrier layer pattern 112 extending in the first direction, the conductive layer patterns 122 and the capping layer patterns 132. A plurality of stack structures each including the line-shaped barrier layer pattern 112, the conductive layer patterns 122 and the capping layer patterns 132 may be formed to be spaced apart from each other.

In example embodiments, the spacer 140 may be formed at both sidewalls of the stack structure (112, 122, and 132). More specifically, a material layer to be used as the spacer 140 may be formed on the entire surface of the resultant structure having the stack structure (112, 122, and 132) and the material layer is blanket etched, thereby forming the spacer 140. Here, the material layer used as the spacer 140 may be formed by deposition of an insulating material, for example, silicon oxide, silicon nitride or silicon oxynitride on sidewalls of the barrier layer pattern 112, the conductive layer patterns 122, and the capping layer patterns 132.

As the result, a portion of the first surface S1 of the semiconductor substrate 100 is exposed by the stack structure (112, 122, and 132) and the spacer 140 formed at the sidewalls thereof, so that the conductive layer patterns 122 resulting from the process forms a buried wiring to be described later.

As described above, a direction in which the conductive layer patterns 122 and the buried wiring extend is referred to as a first direction, and a direction crossing the first direction on the same plane is referred to as a second direction.

Referring to FIG. 6, the semiconductor substrate 100 may be anisotropically etched to a depth using the capping layer patterns 132 and the spacer 140 as etch masks, thereby forming the line-shaped semiconductor patterns 104 disposed under the stack structure (112, 122 and 132) and the spacer 140 and extending in the first direction. In example embodiments, the semiconductor substrate 100 may be anisotropically etched to a predetermined depth. The line-shaped semiconductor patterns 104 and the stack structure (112, 122 and 132) may planarly overlap each other, so that they have a similar shape. Here, a second direction width w1 of the semiconductor patterns 104 may be a second direction width of the spacer 140 which may be greater than that of the stack structure (112, 122 and 132).

In example embodiments, a depth in which the semiconductor substrate 100 is etched, that is, a height h1 of the semiconductor patterns 104, may be smaller than a thickness of the semiconductor substrate 100. In addition, the etched depth may be smaller than a thickness of the upper part 100a of the semiconductor substrate 100. Accordingly, the bottommost part of the semiconductor patterns 104 may be spaced a distance apart from the ion implantation layer 102. In example embodiments, the distance between the bottommost part of the semiconductor patterns 104 and the ion implantation layer 102 may or may not be predetermined. As described above, the height h1 of the semiconductor patterns 104 may be adjusted to prevent or reduce defects from being generated. However, some defects may be unavoidably generated around the ion implantation layer 102 in forming the ion implantation layer 102. Since the semiconductor patterns 104 may be provided as an active region in a subsequent process to form a semiconductor device, for example, a transistor, it is desirable that defects should not be generated or at least be minimized.

The plurality of semiconductor patterns 104 formed as the result of the above processes are not separated from each other, as they are connected to each other by the upper part 100a of the semiconductor substrate 100 under the semiconductor patterns 104.

Referring to FIG. 7, the insulating layer 150 may be formed on the stack structure (112, 122 and 132), the spacer 140, and the semiconductor patterns 104. In example embodiments, the insulating layer 150 may be formed to a thickness enough to cover a top portion of the stack structure (112, 122 and 132) while filling a space between the spacer 140 and the semiconductor patterns 104.

The insulating layer 150 may be formed using various deposition methods, for example, sputtering or chemical vapor deposition (CVD). In example embodiments, the insulating layer 150 may be deposited at a temperature of 500° C. or lower. In addition, the insulating layer 150 may include a silicon oxide layer. The silicon oxide layer may include a high density plasma (HDP) oxide layer, a spin on glass (SOG) oxide layer, a tetraethyl orthosilicate (TEOS) layer, an oxide layer foinied by radical oxidation, and so on.

As shown, the insulating layer 150 may have a planarized surface. To this end, after depositing an insulation material for forming the insulating layer 150, a planarizing process, for example, a chemical mechanical polishing (CMP) process, may further be performed. The planarized surface of the insulating layer 150 may be a surface for bonding to a supporting substrate 160 to be described later.

The insulating layer 150 may be provided as an isolation region that separates the semiconductor patterns 104 from each other, the semiconductor patterns 104 provided as an active region when a semiconductor device, for example, a transistor, using the substrate structure in a subsequent process. In example embodiments, the semiconductor device may or may not be prefabricated or predetermined.

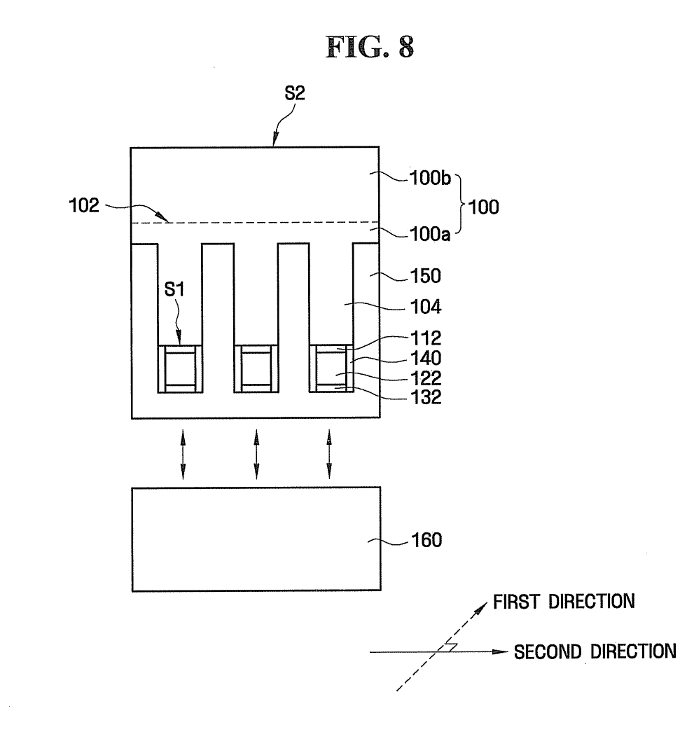

Referring to FIG. 8, the supporting substrate 160 may be provided. As described above, the supporting substrate 160 may be any one selected among a single crystalline silicon substrate, an amorphous silicon substrate, a polysilicon substrate. In addition, the supporting substrate 160 may include even a substrate including crystal defects or particles. In addition, even a low-level substrate determined as an inappropriate substrate in forming an element may be used as the supporting substrate 160.

In example embodiments, the insulating layer 150 may be bonded to the supporting substrate 160 such that a top surface of the supporting substrate 160 contacts a top surface of the insulating layer 150. In other words, the insulating layer 150 is bonded to the supporting substrate 160 such that the first surface S1 of the semiconductor substrate 100 faces the top surface of the supporting substrate 160 by reversing the resultant product of the process shown in FIG. 7.

The bonding process will now be described in more detail. The top surface of the supporting substrate 150 and the top surface of the insulating layer 150 may be hydrophilized by, for example, adding water thereto, and the hydrophilized top surfaces of the supporting substrate 150 and the insulating layer 150 may be brought into contact with each other. Then, the supporting substrate 160 and the insulating layer 150 may be bonded to each other by a Van der Waals force applied between OH groups formed on the contact surface. The bonding process may be performed at a temperature of 500° C. or lower, for example, in a range of room temperature to 400° C. Since a material that is not easily bonded, such as a metallic material, is not exposed to a bonding surface during the bonding process, bonding is easily achieved and two substrates, that is, the semiconductor substrate 100 and the supporting substrate 160, can be accurately bonded to each other without being loosened. However, example embodiments do not limit the bonding process to that illustrated herein, and the bonding process may be performed in various manners.

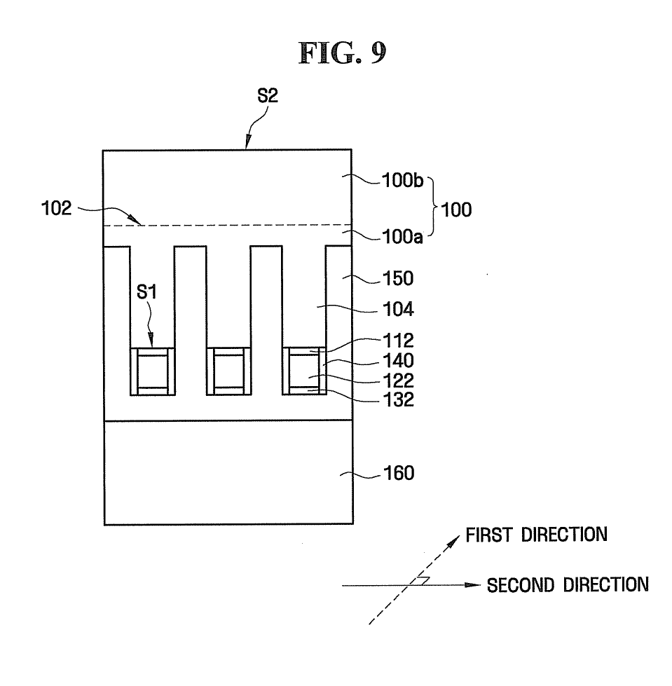

As the result of the bonding, as shown in FIG. 9, the resultant product of the process shown in FIG. 7 is disposed upside down on the supporting substrate 160. Accordingly, the first surface S1 of the semiconductor substrate 100 faces the top surface of the supporting substrate 160 and the second surface S2 of the semiconductor substrate 100 is a top surface of the resultant structure of FIG. 9. In addition, the stack structure 132, 122, 112) having the capping layer patterns 132, the conductive layer patterns 122 and the barrier layer pattern 112 sequentially stacked is buried in the insulating layer 150 while extending in the first direction, and the semiconductor patterns 104 extending in the first direction are disposed in the insulating layer 150 and on the stack structure (132, 122, 112).

Referring to FIG. 10, the semiconductor substrate 100 may be cut along the previously formed ion implantation layer 102 to remove the lower part 100b of the semiconductor substrate 100 while only the upper part 100a of the semiconductor substrate 100 remains. The cutting may be performed by thermally treating the semiconductor substrate 100 at a temperature of 500° C. or higher.

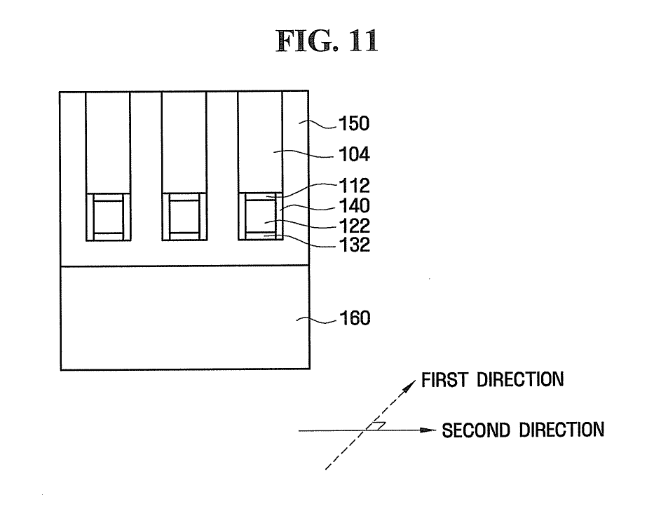

In example embodiments, the upper part 100a of the semiconductor substrate 100 resulting from the cutting may have an unsmooth surface or may include defects generated in the forming of the ion implantation layer 102 (see FIG. 3). However, these problems may be in solved or minimized while performing the process shown in FIG. 11, which will later be described.

Referring to FIG. 11, the upper part 100a of the semiconductor substrate 100 remaining to expose the insulating layer 150 may be removed. As the result, the plurality of semiconductor patterns 104 connected to each other by the upper part 100a of the semiconductor substrate 100 may be separated from each other by the insulating layer 150. Accordingly, when a semiconductor device, for example, a transistor, is used in a subsequent process, the semiconductor patterns 104 may be provided as an active region and the insulating layer 150 may be provided as an isolation region that separates the semiconductor patterns 104 from each other. In addition, the conductive layer patterns 122 as buried wirings may be disposed under the semiconductor patterns 104 provided as the active region and thus may be used as wirings, for example, bit lines, necessary when a device, for example, a transistor, is formed or used in a subsequent process.

The removing of the upper part 100a of the semiconductor substrate 100 may be performed by polishing, for example, CMP, or dry etching.

In this process, the semiconductor patterns 104 may be separated from each other and the problems, including have an unsmooth surface of the upper part 100a of the semiconductor substrate 100 resulting from the process shown in FIG. 10 or defects generated in the forming of the ion implantation layer 102, may be solved or minimized. This is because the surface of the upper part 100a of the semiconductor substrate 100 may be removed in this process.

As the result of the processes shown in FIGS. 3 to 11, the substrate structure shown in FIGS. 1 and 2 may be manufactured, but not limited thereto. Alternatively, the substrate structure shown in FIGS. 1 and 2 may also be manufactured by other methods.

According to the above-described substrate structure and manufacturing method thereof, at least the following effects can be achieved.

That is to say, since the substrate structure of example embodiments may include low-resistance buried wirings, the characteristics of the semiconductor device may be improved.

In addition, because the conductive layer to be used as the buried wiring is first patterned and the semiconductor substrate to be used as the active region is then patterned, the problems generated in the patterning can be solved. In detail, like in the recent technologies, if the active region is first patterned and the conductive layer is then patterned, metallic materials or byproducts generated in the patterning of the conductive layer may be adhered to sidewalls of the active region, resulting in contamination of the active region. In the manufacturing method of the substrate structure according to example embodiments, the patterning sequence may be changed to solve or minimize the problems.

Further, since the substrate structure according to example embodiments has the buried conductive layer, the patterned conductive layer itself may be used as a wiring, thereby simplifying and facilitating subsequent device forming processes.

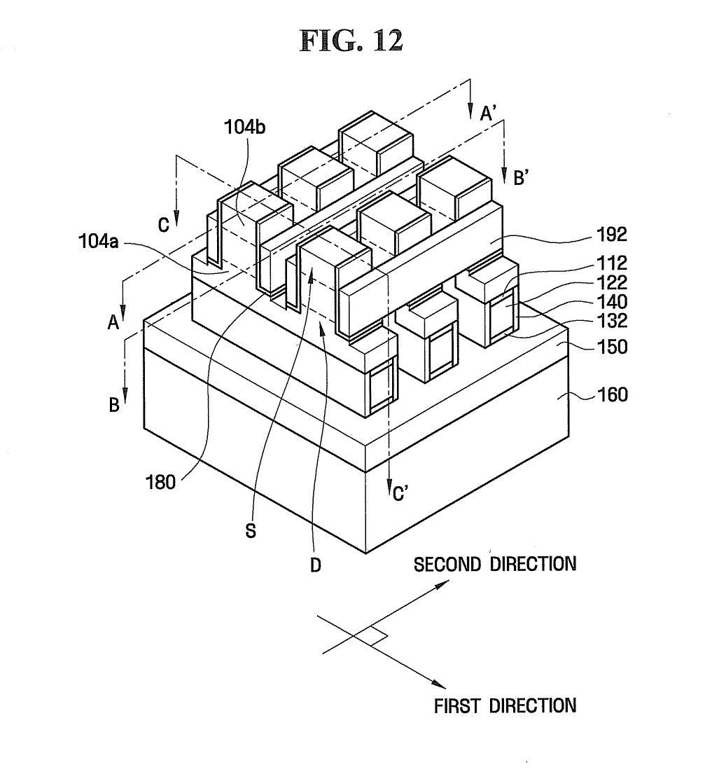

Meanwhile, since the above-described substrate structure has an active region and an isolation region while having a buried wiring, it can be used in manufacturing a variety of semiconductor devices. For example, the above-described substrate structure can be used in manufacturing a semiconductor device having a vertical channel transistor. In this case, a buried wiring may be used as a bit line, an example of which will be described below in more detail with reference to FIGS. 12 to 18.

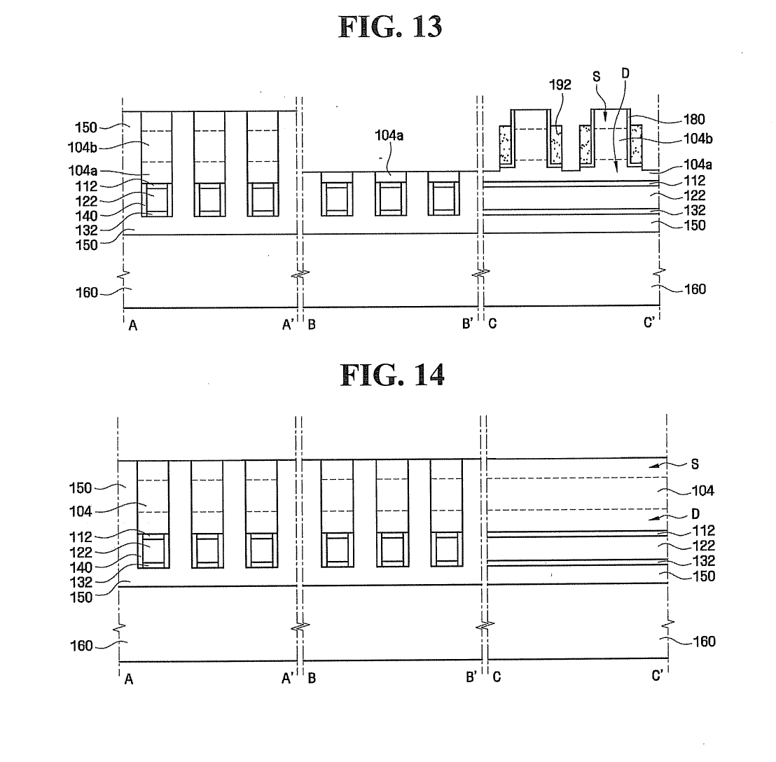

FIG. 12 is a perspective view of a semiconductor device according to example embodiments, and FIG. 13 is a cross-sectional view of the semiconductor device shown in FIG. 12, taken along lines A-A′, B-B′ and C-C′. Here, the line A-A′ of FIG. 12 is identical with the line A-A′ of FIG. 1. In FIG. 12, in order to clearly indicate components included in the semiconductor device according to example embodiments, only part of an insulating layer 150, specifically only a portion of the insulating layer 150 below a buried wiring, is indicated in the drawing. However, it is noted that the insulating layer 150 shown in FIG. 12 may be substantially the same as that shown in FIG. 13.

The example semiconductor device illustrated in FIGS. 12 and 13 may be manufactured using substantially the same substrate structure as previously described.

Referring to FIGS. 12 and 13, the semiconductor device according to example embodiments may include a supporting substrate 160, an insulating layer 150 disposed on the supporting substrate 160, line-shaped conductive layer patterns 122 buried in the insulating layer 150 and extending in a direction, for example, in a first direction, an active region disposed on the conductive layer patterns 122 and including line-shaped lower semiconductor patterns 104a and pillar-shaped upper semiconductor patterns 104b, and a transistor disposed in the active region. The respective components of the substrate structure according to example embodiments will now be described in more detail.

The supporting substrate 160 included in the semiconductor device according to example embodiments, and the conductive layer patterns 122 buried in the insulating layer 150 may be substantially the same as those described in FIGS. 1 and 2. Barrier layer patterns 112 disposed on the conductive layer patterns 122, capping layer patterns 132 disposed under the conductive layer patterns 122, and spacers 140 disposed on both sidewalls of the stack structure (132, 122, and 112) may also substantially the same as those shown in FIGS. 1 and 2. The conductive layer patterns 122 may be used as buried wirings, specifically bit lines, in the semiconductor device according to example embodiments, which will later be described.

The line-shaped lower semiconductor patterns 104a and the pillar-shaped upper semiconductor patterns 104b may be formed by additionally patterning the semiconductor patterns 104 shown in FIGS. 1 and 2. In detail, the line-shaped lower semiconductor patterns 104a are portions of the semiconductor patterns 104 that are not patterned and are disposed on the stack structure (132, 122, and 112), while extending in a first direction. The pillar-shaped upper semiconductor patterns 104b are formed by patterning top portions of the semiconductor patterns 104 and are disposed on the lower semiconductor patterns 104a while vertically protruding from the lower semiconductor patterns 104a. Here, a plurality of upper semiconductor patterns 104b may be disposed on one of the lower semiconductor patterns 104a. In addition, example embodiments show that the upper semiconductor patterns 104b have rectangular pillar shapes, but the present invention is not limited thereto. Alternatively, the upper semiconductor patterns 104b may be shaped of a cylinder or polyprism. Meanwhile, it is noted that dotted lines of the lower semiconductor patterns 104a and the upper semiconductor patterns 104b are used to indicate source/drain regions (S/D), rather than discriminating the lower and upper semiconductor patterns 104a and 104b.

In the following description, for convenience of explanation, a plurality of upper semiconductor patterns 104b arranged in a first direction are referred to columns of the upper semiconductor patterns 104b, and a plurality of upper semiconductor patterns 104b arranged in a second direction are referred to rows of the upper semiconductor patterns 104b. In FIG. 12, the number of columns of the upper semiconductor patterns 104b is 3 and the number of rows of the upper semiconductor patterns 104b is 2. However, example embodiments are not limited thereto.

In example embodiments, the insulating layer 150 disposed between the rows of the upper semiconductor patterns 104b may be etched to a depth corresponding to a height of the upper semiconductor patterns 104b to then be removed. Accordingly, a height of a top surface of the insulating layer 150 between rows of the upper semiconductor patterns 104b is substantially the same as a height of a top surface of the lower semiconductor patterns 104a, and both sidewalls of the upper semiconductor patterns 104b may be exposed in the first direction. In addition, active regions adjacent to each other in the second direction, that is, the lower semiconductor patterns 104a and the upper semiconductor patterns 104b, may be separated from each other by the insulating layer 150.

A transistor may be formed in the active region including the lower semiconductor patterns 104a and the upper semiconductor patterns 104b. The transistor may include a gate insulating layer 180, a gate electrode, a source region S and a drain region D of a gate line 192. As shown, since the source region S and the drain region D are disposed up and down, the transistor has a channel substantially vertical to the supporting substrate 160.

The gate insulating layer 180 may be disposed on at least opposing exposed sidewalls of the upper semiconductor patterns 104b. The gate insulating layer 180 may include, for example, silicon oxide.

The gate line 192 may be disposed between rows of the upper semiconductor patterns 104b and may extend in a second direction while contacting the gate insulating layer 180. A portion of the gate line 192 contacting the gate insulating layer 180 and capable of applying a voltage to a channel of the upper semiconductor patterns 104b is referred to as a gate electrode. Since the lower semiconductor patterns 104a and the insulating layer 150 having substantially the same depth are disposed between the rows of the upper semiconductor patterns 104b, the gate line 192 is disposed on the upper semiconductor patterns 104b.

In example embodiments, two gate lines 192 may be disposed on one row of the upper semiconductor patterns 104b. That is to say, one gate line 192 may contact one sidewall of one row of the upper semiconductor patterns 104b and the other gate line 192 may contact the other sidewall facing the one sidewall. The gate lines 192 may be separated from each other between the rows of the upper semiconductor patterns 104b. The gate lines 192 may include doped polysilicon, a metal, a metal compound, and the like. For example, the gate lines 192 may include tungsten, titanium, aluminum, tantalum, tungsten nitride, aluminum nitride, titanium nitride, titanium aluminum, tungsten silicide, titanium silicide, and cobalt silicide, which may be used alone or in combination.

In example embodiments, a height of the gate line 192 may be substantially smaller than that of each of the upper semiconductor patterns 104b. That is to say, part of the top portion of each upper semiconductor pattern 104b may protrude upwardly relative to the gate line 192.

The source region S may be disposed on the lower semiconductor patterns 104a while being disposed on the upper semiconductor pattern 104b upwardly protruding relative to the gate line 192. The drain region D may be disposed on the lower semiconductor patterns 104a while being disposed under the upper semiconductor pattern 104b upwardly protruding relative to the gate line 192. Vertical locations of the source region S and the drain region D may be adjusted to a certain extent. For example, the topmost part of the drain region D may be slightly higher than the bottommost part of the gate line 192. Alternatively, the bottommost part of the source region S may be slightly lower than the topmost part of the gate line 192. The source/drain regions S/D may include substantially the same impurity, for example, N-type impurity. By contrast, a channel region disposed between the source/drain regions S/D may include impurity, for example, P-type impurity, different from that included in the source/drain regions S/D.

The drain region D may be disposed on the lower semiconductor patterns 104a and may extend in a first direction that is the same direction as the direction in which the lower semiconductor patterns 104a extend. Since a bottom surface of the drain region D may contact a buried wiring, that is, the conductive layer pattern 122 disposed thereunder, the drain region D and the buried wiring may be electrically connected to each other. In this case, since the buried wiring having a relatively low resistance is provided as a bit line, electrical characteristics of the semiconductor device according to example embodiments can be improved. Further, since the semiconductor device according to example embodiments has a vertical channel transistor, the integration level of the semiconductor device may be improved.

Although not shown, a capacitor (not shown) electrically connected to the source region S may be further disposed on the upper semiconductor patterns 104b. In this case, a semiconductor memory device having a unit cell of a 1T 1C (1 transistor 1 capacitor) structure, for example, DRAM, may be achieved.

In example embodiments, the semiconductor device having a vertical channel transistor has been described. In particular, example embodiments have shown the semiconductor device having two gate lines 192 disposed on one row of the upper semiconductor patterns 104b, the two gate lines 192 including one gate line 192 contacting one sidewall of one row of the upper semiconductor patterns 104b and the other gate line 192 contacting the other sidewall facing the one sidewall. However, the present invention is not limited to the example illustrated herein. According to the present invention, as long as a gate line extends in a second direction perpendicular to a first direction while a portion of the gate line (that is, a gate electrode) contacts at least one surface of the upper semiconductor pattern 104b, shapes and numbers of the gate electrode and/or the gate line may be changed in various manners.

FIGS. 14 to 18 illustrate processes in a method of manufacturing the substrate structure shown in FIGS. 12 and 13. Particularly, FIGS. 14 to 18 are cross-sectional views taken along the lines A-A′, B-B′ and C-C′ of FIG. 12.

The semiconductor device according to example embodiments may be manufactured using substantially the same substrate structure as the substrate structure previously described.

First, substantially the same substrate structure as that shown in FIGS. 1 and 2 is provided. That is to say, a substrate structure is provided. As described previously, the substrate structure may include a supporting substrate 160, an insulating layer 150 disposed on the supporting substrate 160, a plurality of stack structures (132, 122, and 112) disposed in the insulating layer 150, extending in a first direction, and having capping layer patterns 132, conductive layer patterns 122 and barrier layer patterns 112 sequentially stacked, spacers 140 disposed on opposing sidewalls of each of the stack structures (132, 122, and 112), and semiconductor patterns 104 disposed on the stack structure (132, 122, and 112) and the spacers 140, and having a top surface exposed to the outside of the insulating layer 150 while extending in the first direction. The substrate structure may be formed by performing the processes shown in FIGS. 3 to 11, but example embodiments are not limited thereto.

Referring to FIG. 14, in order to form a source region and a drain region in the semiconductor pattern 104 provided as the active region, an ion implantation process is performed. Here, the source region S disposed on the semiconductor pattern 104 and the drain region D disposed under the semiconductor pattern 104 may be separately foimed by adjusting ion implantation energy. The source region S and the drain region D may be disposed up and down and spaced a distance apart from each other, and a channel may be vertically formed at a portion of the semiconductor pattern 104 between the source region S and the drain region D. In example embodiments, the distance between the source region S and the drain region D may be predetermined. The source/drain regions S/D may be formed by implanting impurity of a first conductivity type (for example, N-type impurity).

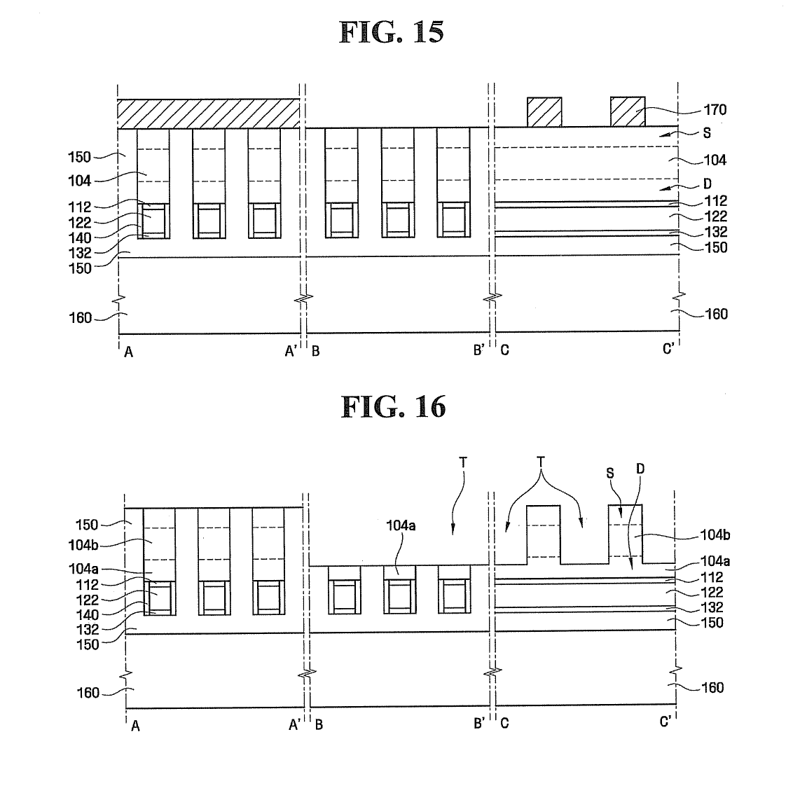

Referring to FIG. 15, a mask pattern 170 may be formed on the substrate structure resulting from the ion implantation. The mask pattern 170 may be provided for additionally patterning the semiconductor pattern 104 to be used to form an active region having a desired shape. For example, in order to form a vertical channel transistor, a pillar-shaped semiconductor pattern that vertically protrudes from a surface of a semiconductor substrate may be required as the active region. Thus, the mask pattern 170 may have a variety of shapes so as to pattern an active region as required by a device. While example embodiments show that the mask pattern 170 is shaped of a line extending in a second direction to form a pillar-shaped active region, the invention is not limited thereto and a mask pattern having an island shape, for example, polygon or circle, may also be used.

Referring to FIG. 16, the semiconductor pattern 104 may be etched to a depth using the line-shaped mask pattern 170 extending in the second direction as an etch mask. In example embodiments, the etched depth may or may not be predetermined. In example embodiments, the semiconductor pattern 104 may be etched until a portion near the topmost part of the drain region D is reached. As the result, like in the conventional semiconductor pattern 104, a line-shaped lower semiconductor pattern 104a and a pillar-shaped upper semiconductor pattern 104b are formed, the line-shaped lower semiconductor pattern 104a disposed on a stack structure (132, 122, and 112) and extending in the first direction and the pillar-shaped upper semiconductor pattern 104b disposed on the lower semiconductor pattern 104a and vertically protruding from the lower semiconductor pattern 104a. Here, a plurality of upper semiconductor patterns 104b may be formed on one lower semiconductor pattern 104a according to the number of the mask pattern 170. While example embodiments show that upper semiconductor pattern 104b has a square pillar shape, the invention is not limited thereto. Rather, the upper semiconductor pattern 104b may be shaped of a cylinder or polyprism according to the shape of the mask pattern 170. In this process, the etching depth may be adjusted such that the bottommost part of the upper semiconductor pattern 104b is at the same height as or slightly lower than the topmost part of the drain region D.

As described above, in this embodiment, in order to form a vertical channel transistor, the active region is constituted by the lower semiconductor pattern 104a and the upper semiconductor pattern 104b formed by additionally etching the semiconductor patterns 104.

In this process, in addition to the etching of the semiconductor substrate 104 using the mask pattern 170 as an etch mask, the insulating layer 150 may be additionally etched using the mask pattern 170 as an etch mask. That is to say, the semiconductor substrate 104 and the insulating layer 150 may be collectively etched using the mask pattern 170 as an etch mask. Accordingly, a top surface of the etched insulating layer 150 may be at the same height as the top surface of the lower semiconductor pattern 104a. As described above, a space (to be referred to as a trench (T) hereinafter) in which a gate line can be formed may provided between columns of the upper semiconductor pattern 104b by collectively etching the semiconductor substrate 104 and the insulating layer 150. The forming of the gate line will later be described.

When the semiconductor substrate 104 and/or the insulating layer 150 exposed by the mask pattern 170 are etched, opposing sidewalls of the upper semiconductor pattern 104b may be exposed in a first direction. An ion implantation process for forming a channel is performed on the opposing sidewalls of the thus exposed upper semiconductor pattern 104b. The ion implantation process may be performed such that impurity is implanted into the sidewalls of the upper semiconductor pattern 104b between the source region S and the drain region D. In order to form the channel, impurity of a second conductivity type different from that of the source/drain regions S/D, for example, P-type impurity, may be implanted into the upper semiconductor pattern 104b.

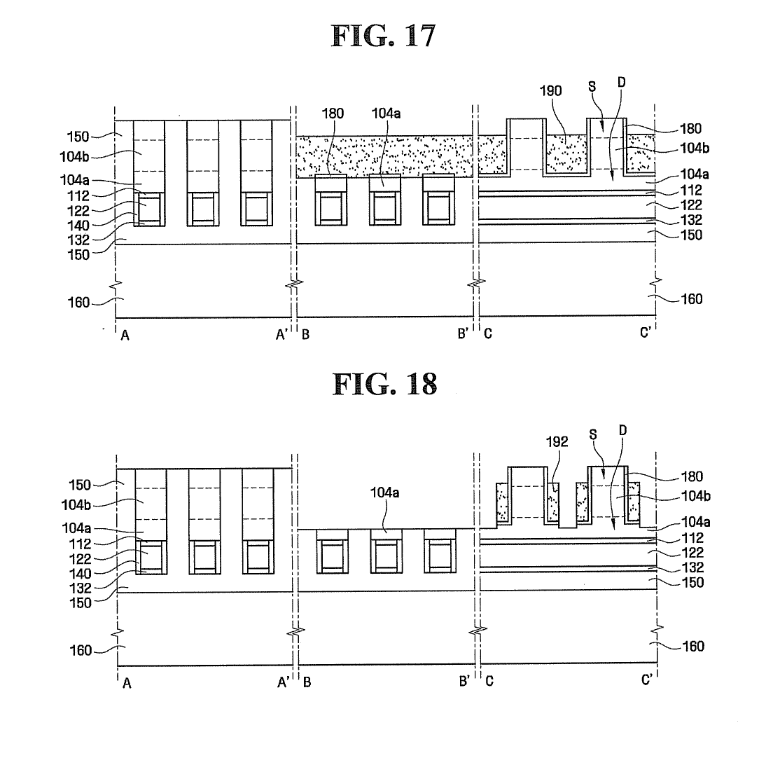

Next, referring to FIG. 17, a gate insulating layer 180 may be formed on opposing sidewalls of the exposed upper semiconductor pattern 104b. The gate insulating layer 180 may be provided for insulating the upper semiconductor pattern 104b from a gate line to be described later. The gate insulating layer 180 may include, for example, silicon oxide, and may be formed by thermal oxidation. If the gate insulating layer 180 is formed by, for example, thermal oxidation, as shown in FIG. 17, the gate insulating layer 180 may also be formed on the exposed upper semiconductor pattern 104b, for example, on a top surface of the lower semiconductor pattern 104a, as well as the opposing sidewalls of the upper semiconductor patterns 104b.

In example embodiments, a conductive layer (not shown) for forming gate lines may be formed on the entire surface of the resultant structure and the conductive layer may be blanket etched to reduce its height. As the result, a conductive pattern 190 for forming gate lines, buried in the trench (T of FIG. 16) between the rows of the upper semiconductor patterns 104b, is formed. The conductive pattern 190 may be formed to have its top surface height the same as or slightly higher than a region around the source region S, that is, the bottommost part of the source region S while being buried in the space T. Accordingly, the conductive pattern 190 may be fanned to contact at least a channel region of the opposing sidewalls of the upper semiconductor patterns 104b while extending in the second direction.

In example embodiments, the conductive pattern 190 may be disposed between the rows of the upper semiconductor patterns 104b. Here, the conductive pattern 190 may contact both one row of the upper semiconductor patterns 104b and another row adjacent to the one row. Therefore, it may be necessary to cut the conductive pattern 190 between the rows, and the process of FIG. 18 is performed accordingly.

Referring to FIG. 18, a central portion of the conductive pattern 190 disposed between the rows of the upper semiconductor patterns 104b may be etched in the first direction, thereby forming gate lines 192 separated from each other. Accordingly, two gate lines 192, that is, one gate line 192 contacting one sidewall of one row of the upper semiconductor patterns 104b and the other gate line 192 contacting the other sidewall facing the one sidewall, may be disposed for each row of the upper semiconductor patterns 104b.

In example embodiments, in order to completely cut the conductive pattern 190, the conductive pattern 190 should be over-etched to a certain extent. Thus, the gate insulating layer 180 exposed by etching the conductive pattern 190 or the lower semiconductor pattern 104a or insulating layer 150 disposed thereunder may be etched together.

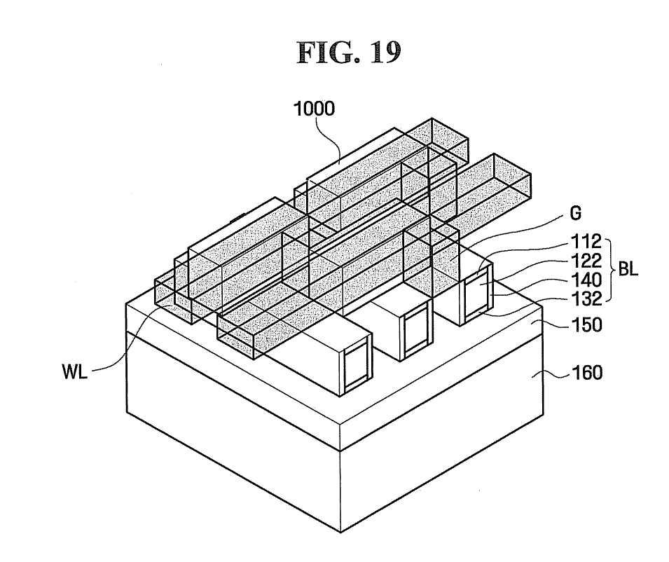

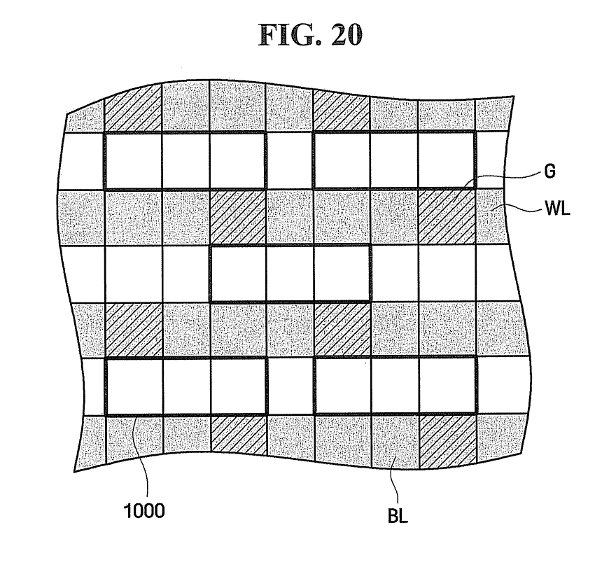

Next, a semiconductor device according to example embodiments will be described with reference to FIGS. 19 and 20. FIG. 19 is a perspective view of a semiconductor device according to example embodiments, and FIG. 20 is a plan view of the semiconductor device shown in FIG. 19. The semiconductor device according to example embodiments may be manufactured using an intermediate structure obtained in the course of forming the substrate structure as shown in FIG. 1, that is, the structure shown in FIG. 5. In order to clearly indicate components included in the semiconductor device according to example embodiments, FIG. 19 shows only part of FIG. 20, that is, active regions disposed in two rows and two word lines while omitting part of an insulating layer and an isolation layer.

Referring to FIGS. 19 and 20, the semiconductor device according to example embodiments may include a supporting substrate 160, an insulating layer 150 disposed on the supporting substrate 160, line-shaped conductive layer patterns 122 buried in the insulating layer 150 and extending in a direction, for example, in a first direction, pillar-shaped semiconductor patterns 1000 disposed on the conductive layer patterns 122 as an active region, and two transistors disposed on each of the semiconductor patterns 1000. The respective components of the semiconductor device according to example embodiments will now be described in more detail.

The supporting substrate 160 included in the semiconductor device according to example embodiments, and the conductive layer patterns 122 buried in the insulating layer 150 may be substantially the same as those described in FIGS. 1 and 2. In addition, barrier layer patterns 112 disposed on the conductive layer patterns 122, capping layer patterns 132 disposed under the conductive layer patterns 122, and spacers 140 disposed on both sidewalls of the stack structure (132, 122, and 112) may also be substantially the same as those shown in FIGS. 1 and 2. The conductive layer patterns 122 may be used as buried wirings, specifically bit lines, in the semiconductor device according to example embodiments.

The pillar-shaped upper semiconductor patterns 1000 may be formed by patterning the semiconductor substrate 100 as shown in FIG. 5. The semiconductor pattern 1000 may have a substantially rectangular shape and may have a second direction width greater than a first direction width. The semiconductor pattern 1000 may be divided into three parts by bit lines BL disposed thereunder in a second direction. That is to say, the center of the semiconductor pattern 1000 may overlap the bit lines BL and opposing sides of the center overlap a region between the bit lines BL. In the following description, for convenience of explanation, a portion of the semiconductor pattern 1000 overlapping the bit line BL is referred to as the center, a portion of the semiconductor pattern 1000 in the left of the center is referred to as a first side, and a portion of the semiconductor pattern 1000 in the right of the center is referred to as a second side.

The semiconductor pattern 1000 may have two opposing side surfaces in the second direction. Channel regions may be disposed at first and second side surfaces of the semiconductor pattern 1000 corresponding to the first and second sides of the semiconductor pattern 1000. In addition, first and second source regions may be disposed on the semiconductor pattern 1000 corresponding to the first and second sides of the semiconductor pattern 1000, and a common drain region may be formed under the semiconductor pattern 1000 corresponding the to the center of the semiconductor pattern 1000. The common drain region may be directly connected to the bit line BL

Here, a plurality of semiconductor patterns 1000 may be arranged in a zigzag configuration while overlapping the bit line BL. That is to say, if the plurality of semiconductor patterns 1000 existing on a column are arranged to overlap the bit line BL of, for example, an odd-numbered row, the plurality of semiconductor patterns 1000 existing on an adjacent column of the column may be arranged to overlap the bit line BL pattern of, for example, an even-numbered row. Accordingly, a first side of the semiconductor pattern 1000 existing on a column may face a second side of the semiconductor pattern 1000 existing on its adjacent column.

An isolation layer (not shown) may be present between these semiconductor patterns 1000 to separate the same from each other except for a space where a gate electrode G to be described later.

The gate electrode G may be disposed between a first side of the semiconductor pattern 1000 of one column and a second side of the semiconductor pattern 1000 of another column adjacent to the one column. A word line WL may be disposed above the isolation layer (not shown) between columns of the semiconductor pattern 1000 and may extend in a second direction while connecting the gate electrode G.

With this configuration, two transistors having first and second channels may be formed for each of the semiconductor patterns 1000 separated by the isolation layer and share a drain region. That is to say, a highly integrated device can be achieved by forming two memory cells in an active region.

While the present invention has been particularly shown and described with reference to example embodiments thereof, it will be understood by those of ordinary skill in the art that various changes in form and details may be made therein without departing from the spirit and scope of the present invention as defined by the following claims. It is therefore desired that example embodiments be considered in all respects as illustrative and not restrictive, reference being made to the appended claims rather than the foregoing description to indicate the scope of the invention.

1-7. (canceled)

8. A method of manufacturing a substrate structure comprising:
forming a conductive layer on one surface of a semiconductor substrate;
forming a line-shaped conductive layer pattern extending in a first direction by patterning the conductive layer;
forming a line-shaped semiconductor pattern under the conductive layer pattern and extending in the first direction by etching the semiconductor substrate exposed by the conductive layer pattern to a depth;
forming an insulating layer on the conductive layer pattern and the semiconductor pattern;
disposing the insulating layer on a supporting substrate such that the one surface of the semiconductor substrate faces the supporting substrate; and
removing a portion of the semiconductor substrate such that the insulating layer is exposed from a second surface of the semiconductor substrate.

9. The method of claim 8, wherein the conductive layer pattern includes one of a metal and a metal silicide material, and the semiconductor pattern includes a single crystalline semiconductor material.

10. The method of claim 8, further comprising:
forming a barrier layer on the semiconductor substrate before forming the conductive layer, wherein the barrier layer is patterned when the conductive layer is patterned so that a barrier layer pattern is formed under the conductive layer pattern.

11. The method of claim 10, wherein the barrier layer pattern includes at least one of a metal, metal nitride and a metal silicide material.

12. The method of claim 8, wherein the conductive layer pattern is surrounded by a capping layer pattern on its bottom surface and a spacer at its sidewalls, and forming the line-shaped semiconductor pattern includes using the capping layer pattern and the spacer as etch masks.

13. The method of claim 12, wherein at least one of the capping layer pattern and the spacer includes silicon oxide, silicon nitride or silicon oxynitride.

14. The method of claim 8, further comprising:
forming an ion implantation layer in the semiconductor substrate, the ion implantation layer being formed to a depth from the one surface of the semiconductor substrate, and removing the portion of the semiconductor substrate includes cutting the semiconductor substrate using the ion implantation layer as a cut surface.

15. The method of claim 14, wherein a height of the line-shaped semiconductor pattern is smaller than the depth of the ion implantation layer and removing the portion of the semiconductor substrate further includes one of polishing and etching the cut semiconductor substrate to expose the insulating layer after the semiconductor substrate is cut.

16. The method of claim 14, wherein cutting the semiconductor substrate includes thermally treating the semiconductor substrate at a temperature greater than or equal to a reference temperature, and the processes preceding the cutting of the semiconductor substrate are performed at a temperature lower than the reference temperature.

17. The method of claim 8, wherein disposing the insulating layer on the supporting substrate includes, in a state in which one surface of the insulating layer and one surface of the supporting substrate are hydrophillized, respectively, bonding the one surface of the insulating layer to the one surface of the supporting substrate.

18-22. (canceled)

23. The method of claim 8, further comprising:
forming a line-shaped lower semiconductor pattern on the conductive layer pattern to extend in the first direction, and a pillar-shaped upper semiconductor pattern on the lower semiconductor pattern, by patterning the line-shaped semiconductor pattern; and
forming a gate line extending in a second direction intersecting with the first direction while contacting at least one sidewall of the upper semiconductor pattern with a gate insulating layer between the upper semiconductor pattern and the gate line.

24. The method of claim 23, wherein patterning the semiconductor pattern includes
forming line-shaped mask patterns on the insulating layer and the line-shaped semiconductor pattern to extend in the second direction intersecting with the first direction; and
etching the semiconductor pattern and the insulating layer to a depth using the mask patterns as etch masks.

25. The method of claim 23, wherein forming the gate line includes forming a first gate line and a second gate line, the first gate line being formed to contact one sidewall of a row of the upper semiconductor pattern arranged in the second direction, and the second gate line being formed to contact another sidewall facing the one sidewall.

26. The method of claim 23, further comprising:
forming a barrier layer on the one surface of the semiconductor substrate before forming the conductive layer on the one surface of the semiconductor substrate, wherein a barrier layer pattern is formed when the line-shaped conductive layer pattern is formed.

27. The method of claim 23, further comprising:
forming a capping layer on the conductive layer, wherein forming the line-shaped conductive layer pattern forms a capping layer pattern on the line-shaped conductive layer pattern.

28. A method of manufacturing a substrate structure comprising:
farming a stacked structure on a surface of a semiconductor substrate, the stacked structure comprising a line-shaped conductive pattern;
etching the semiconductor substrate to faun a line-shaped semiconductor pattern below the line-shaped conductive pattern;
forming an insulating layer on the stacked structure, the line-shaped semiconductor pattern, and the semiconductor substrate;
bonding the insulating layer to a support substrate; and
cutting the semiconductor substrate to expose the insulating layer, wherein the stacked structure is used as an etch mask for forming the line-shaped semiconductor pattern.

29. The method of claim 28, further comprising:
orientating the semiconductor substrate with the insulating layer formed thereon such that the surface of the semiconductor substrate faces a surface of the supporting substrate.

30. The method of claim 29, wherein forming the stacked structure includes forming a barrier layer, a conductive layer, and a capping layer on the semiconductor substrate and etching the barrier layer, the conductive layer, and the capping the layer to form the line-shaped conductive pattern.

31. The method of claim 30, further comprising:
forming a spacer on sides of the line-shaped conductive pattern.

32. The method of claim 31, wherein the spacer is formed on the sides of the line-shaped conductive pattern before the line-shaped semiconductor pattern is formed so that a width of the line-shaped semiconductor pattern is greater than a width of the line-shaped conductive pattern.
